(19) United States
(12) Patent Application Publication
(10) Pub. No.: US 2007/0000684 A1
(43) Pub. Date: Jan. 4, 2007

(54) CIRCUIT BOARD AND VISUAL INSPECTION METHOD OF MOUNT POSITION OF ELECTRONIC COMPONENT

(75) Inventors: Koji HARADA, Minami-ku, Kyoto (JP); Tomohiko NAKATANI, Minami-ku, Kyoto (JP); Tomohiro UMEMURA, Minami-ku, Kyoto (JP)

Correspondence Address: NIDEC CORPORATION;c/o KEATING & BENNETT, LLP, 8180 GREENSBORO DRIVE, SUITE 850, MCLEAN, VA, 22102, US

(73) Assignee: NIDEC CORPORATION, Minami-ku (JP)

(21) Appl. No.: 11/427,072

(22) Filed: Jun. 28, 2006

(30) Foreign Application Priority Data
Jun. 29, 2005 (JP) 2005-189778

(51) Int. Cl. H05K 1/02

(52) U.S. Cl. 174/250; 174/260

(57) ABSTRACT

A circuit board is equipped with soldering lands for a hall element and visual inspection marks printed at a vicinity of the soldering lands. The visual inspection marks include a pair of slender marks arranged so as to sandwich the two soldering lands to which two terminal pins protruding from an edge of the hall element are soldered. When the hall element is mounted at a correct position, tips of the two terminal pins arranged in a row are positioned on a straight line that connects the pair of slender marks. In addition, a third slender mark is printed at a middle position between the pair of slender marks and between the two soldering lands.

### BACKGROUND OF THE INVENTION

1. Field of the Invention

The present invention generally relates to a circuit board of a brushless motor or the like and a method for visually inspecting a position of an electronic component mounted on the circuit board. In particular, the present invention relates to a method for visually inspecting a position of a surface mount component such as a hall element mounted on the circuit board.

2. Description of the Related Art

A brushless motor is usually equipped with a circuit board on which a hall element for detecting magnetic poles of a rotor and electronic components such as a motor driving IC are mounted (see Japanese unexamined patent publications No. 2003-201991 and No. 2003-180064, for example). In a small type motor, it is common to use a double sided printed circuit board as the circuit board and surface mount type electronic components such as the motor driving IC. The surface mount type components are mounted on a surface of the circuit board by means of reflowing or the like, and terminal pins of the component are not inserted in holes of the circuit board but are connected to lands on the surface of the circuit board via solder. Such an electronic component is referred to as a surface mount component.

For example, a hall element that is mounted on a circuit board for a brushless motor has a plastic package of a size approximately 1.2 mm×2 mm in a plan view and four terminal pins protruding from both edges by two pins each (see FIGS. 2A and 2B). End portions of these four terminal pins are connected to soldering lands on the circuit board via solder in a reflowing step. A width of the terminal pin is approximately 0.3 mm, and the soldering land has an elliptical shape of approximately 0.5 mm×0.8 mm, for example.

The surface mount components such as the hall element described above is mounted on the circuit board by using a machine called a mounter (a chip mounter or a component mounter) A set of control data including mount positions of the surface mount components on the circuit board is created and registered in the mounter. The surface mount components are temporarily fixed to the circuit board with a flux or the like, and a heat treatment is performed on the circuit board in a reflow oven, so that the terminal pins of the surface mount component are soldered to the soldering lands. In general, test mounting is performed before real mounting, and deviation of the mount position is checked visually by using a magnifying glass, so that correction of the control data is performed. In the visual test, for example, it is checked whether or not a tip portion of the terminal pin is positioned substantially in the middle of the soldering land.

In addition, the control data for the mounter can be created from a CAD data that was used for manufacturing the circuit board. In this case, mount positions of the surface mount components on the circuit board can be obtained automatically from the CAD data. Actually, however, there may occur some errors in dimensions of the manufactured circuit board due to a print shift, a punch shift or the like in the manufacturing process. Therefore, even if the control data for the mounter is created from the CAD data of the circuit board, it is necessary to go through a series of steps described above, which includes the test mounting, the visual inspection using a magnifying glass, and a correction of the control data.

The above-mentioned visual inspection of the mount positions of the surface mount component such as a hall element on the motor circuit board is difficult to perform accurately because of individual differences of inspection operators. For example, in the case of the above-mentioned hall element, a size of the soldering land on the circuit board is much larger than the width of the terminal pin of the hall element for good soldering property. Therefore, it is difficult to perform the visual inspection of a relative position between them accurately. In particular, it is difficult to detect a position shift in the longitudinal direction of the terminal pin compared with a position shift in the width direction of the same.

In the case of the hall element, if its mount position on the circuit board is shifted, it is difficult to detect a magnetic pole position of a rotor magnet, which may result in failing to control a rotation speed of the motor accurately. Therefore, the mount position of the hall element on the circuit board must be controlled accurately.

### SUMMARY OF THE INVENTION

According to at least one preferred embodiment of the present invention, a circuit board that can facilitate a visual inspection of a mount position of a surface mount component such as a hall element and a method for inspecting the mount position of the surface mount component on the circuit board are provided.

A circuit board on which a surface mount electronic component is mounted according to at least one preferred embodiment of the present invention includes a plurality of soldering lands to which a plurality of terminal pins protruding from an edge of a package of the electronic component are soldered, and visual inspection marks printed at a vicinity of the plurality of soldering lands. The visual inspection marks includes a pair of slender marks arranged so as to sandwich the plurality of soldering lands aligned in a row, and the pair of slender marks are printed so that tips of the plurality of terminal pins of the electronic component that are soldered to the plurality of soldering lands aligned in a row are positioned on a straight line connecting the pair of slender marks. The soldering lands are exposed portions of a conductor such as a copper pattern. In addition, the visual inspection marks can be formed by silk screen printing of a resist ink or the like.

When the circuit board having this structure is used, a visual inspection of a mount position of an electronic component mounted on the circuit board can be performed more accurately and more easily than before. When it is checked whether or not tips of the plurality of terminal pins of the electronic component is on the straight line connecting the pair of slender marks, a position shift of the terminal pins in the longitudinal direction (protruding direction) can be determined accurately and easily. Note that a position shift of the terminal pin in the width direction can be inspected easily by checking whether the terminal pins are positioned uniformly between the pair of slender marks.

According to at least one preferred embodiment of the present invention, the electronic component has total four terminal pins protruding from opposite sides of the package by two pins from each side, and the pair of slender marks are printed in an arrangement such that two soldering lands to which two terminal pins protruding from one side of the package are soldered are sandwiched between the pair of slender marks.

According to at least one preferred embodiment of the present invention, a third slender mark is printed at a middle position between the pair of slender marks and between the two soldering lands. In this structure, since tips of the two terminal pins protruding from one side of the electronic component are positioned between each two of three slender marks printed on the straight line at a constant pitch, not only a position shift in the longitudinal direction (protruding direction) of the terminal pin but also a position shift in the width direction of the terminal pin can be visually inspected more accurately and easily.

According to at least one preferred embodiment of the present invention, a length of the third slender mark in the longitudinal direction is shorter than a length of the pair of slender marks in the longitudinal direction.

According to at least one preferred embodiment of the present invention, a width of the slender mark is within the range of about 0.1 mm to about 0.3 mm, and a length of the same is within the range of about 0.3 mm to about 0.6 mm.

A motor circuit board on which a surface mount electronic component is mounted according to at least one preferred embodiment of the present invention is attached to a motor including a rotor and a stator. The motor circuit board includes a plurality of soldering lands to which a plurality of terminal pins protruding from an edge of a package of the electronic component are soldered, and visual inspection marks printed at a vicinity of the plurality of soldering lands. The visual inspection marks includes a pair of slender marks arranged so as to sandwich the plurality of soldering lands aligned in a row, and the pair of slender marks are printed so that tips of the plurality of terminal pins of the electronic component that are soldered to the plurality of soldering lands aligned in a row are positioned on a straight line connecting the pair of slender marks.

According to at least one preferred embodiment of the present invention, the electronic component is a hall element that is arranged at a position for detecting magnetic poles of a rotor magnet of the rotor, total four terminal pins protrude from opposite sides of the package by two pins from each side, and the pair of slender marks are printed in an arrangement such that two soldering lands to which two terminal pins protruding from one side of the package are soldered are sandwiched between the pair of slender marks. According to this structure, a position shift of a hall element whose mount position must be controlled accurately for the reason described above can be easily detected by a visual inspection.

According to at least one preferred embodiment of the present invention, a third slender mark is printed at a middle position between the pair of slender marks and between the two soldering lands. According to this structure, since each tip of the two terminal pins protruding from one side of the hall element is positioned between each two of three slender marks printed on the straight line at a constant pitch, not only a position shift in the longitudinal direction of the terminal pin but also a position shift in the width direction of the terminal pin can be visually inspected more accurately and easily.

According to at least one preferred embodiment of the present invention, a length of the third slender mark in the longitudinal direction is shorter than a length of the pair of slender marks in the longitudinal direction.

According to at least one preferred embodiment of the present invention, a width of the slender mark is within the range of about 0.1 mm to about 0.3 mm, and a length of the same is within the range of about 0.3 mm to about 0.6 mm. If the slender marks have such dimensions, a position shift between the soldering lands and terminal pins of a small electronic component such as a hall element can be inspected visually by using a magnifying glass easily and accurately.

An inspection method according to at least one preferred embodiment of the present invention is for inspecting visually a mount position of a surface mount electronic component mounted on a circuit board. The method includes the steps of printing a pair of slender marks on the circuit board so that a plurality of soldering lands to which a plurality of terminal pins protruding from an edge of a package of the electronic component are soldered are sandwiched between the pair of slender marks, and inspecting whether or not tips of the plurality of terminal pins of the electronic component aligned in a row are positioned on a straight line connecting the pair of slender marks.

According to this inspection method, a mount position of an electronic component mounted on a circuit board can be visually inspected more accurately and more easily than before. A position shift of a terminal pin in the longitudinal direction (protruding direction) can be visually inspected accurately and easily by checking whether or not tips of the plurality of terminal pins of the electronic component are on the straight line connecting the pair of slender marks. Note that a position shift of the terminal pin in the width direction can be inspected easily by checking whether or not the terminal pins are positioned uniformly between the pair of slender marks.

According to at least one preferred embodiment of the present invention, the electronic component is a hall element having a total of four terminal pins protruding from opposite sides of the package by two pins from each side, and the pair of slender marks are printed on the circuit board so that the pair of slender marks sandwich two soldering lands to which the two terminal pins protruding from the edge. According to this structure, a position shift of a hall element whose mount position must be controlled accurately for the reason described above can be easily detected by a visual inspection.

According to at least one preferred embodiment of the present invention, a third slender mark is printed at a middle position between the pair of slender marks and between the two soldering lands, and it is inspected whether or not the third slender mark is positioned at a middle position between tip portions of the two terminal pins of the mounted electronic component. According to this structure, since each tip of the two terminal pins protruding from one side of the hall element is positioned between each two of three slender marks printed on the straight line at a constant pitch, not only a position shift in the longitudinal direction (protruding direction) of the terminal pin but also a position shift in the width direction of the terminal pin can be visually inspected more accurately and easily.

According to at least one preferred embodiment of the present invention, a width of the slender mark is within the range of about 0.1 mm to about 0.3 mm, and a length of the same is within the range of about 0.3 mm to about 0.6 mm. If the slender marks have such dimensions, a position shift between the soldering lands and terminal pins of a small electronic component such as a hall element can be inspected visually by using a magnifying glass easily and accurately.

Other features, elements, processes, steps, characteristics and advantages of the present invention will become more apparent from the following detailed description of preferred embodiments of the present invention with reference to the attached drawings.

### BRIEF DESCRIPTION OF THE DRAWINGS

FIGS. 1A and 1B are plan view of a first and a second side of a motor circuit board according to a first preferred embodiment of the present invention.

FIGS. 2A and 2B are a plan view and a side elevation view of a hall element that is mounted on the motor circuit board according to the first preferred embodiment of the present invention.

FIG. 3 is a plan view of a mass circuit board that includes a plurality of the motor circuit board shown in FIGS. 1A and 1B.

FIG. 4 is a plan view of a part of the motor circuit board showing a place on which the hall element is mounted and its surrounding patterns with visual inspection marks according to the first preferred embodiment of the present invention.

FIG. 5 is an enlarged view showing a relationship between terminal pins of the hall element and the visual inspection marks according to the first example.

FIG. 6 is an enlarged view showing a relationship between terminal pins of a surface mount component and visual inspection marks according to a second preferred embodiment of the present invention.

### DETAILED DESCRIPTION OF PREFERRED EMBODIMENTS

Preferred embodiments of the present invention will now be described in detail with reference to the attached drawings.

### First Preferred Embodiment

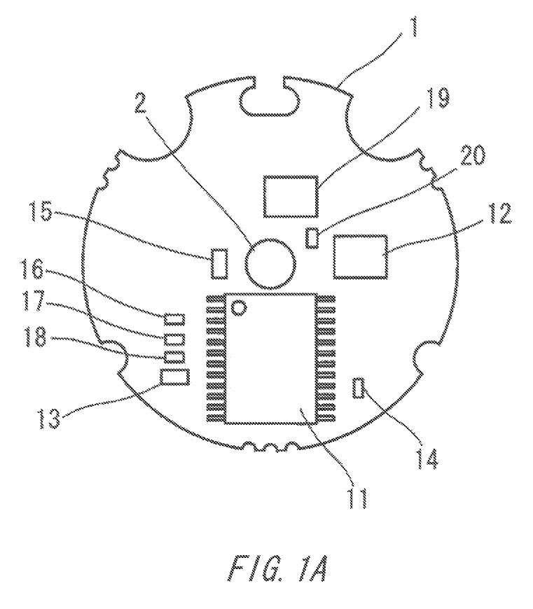

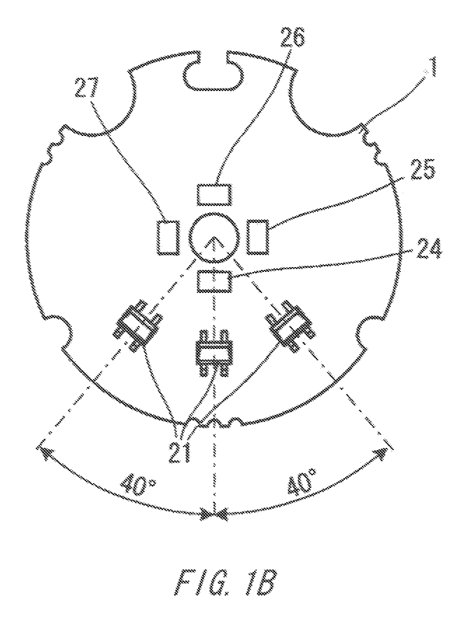

FIGS. 1A and 1B are plan views of a motor circuit board according to a first preferred embodiment of the present invention. FIG. 1A shows a first side (A-side) on which electronic components such as an integrated circuit (IC) for driving a motor are mounted, and FIG. 1B shows a second side (B-side) on which electronic components such as a hall element are mounted. This motor circuit board 1 has substantially a circular shape of a diameter approximately 5 cm and a through hole 2 formed at a center of the board so that a rotation shaft (or a bearing portion) of the motor passes through the through hole 2. The motor circuit board 1 is attached to the motor integrally.

The motor circuit board 1 is a double sided printed circuit board in which circuit patterns (copper patterns) are formed on both sides of a glass epoxy or a paper epoxy substrate. Although there are through holes for electric connection between circuit patterns on the A-side and circuit patterns on the B-side, there are no through holes for mounting components basically. Surface mount type electronic components that require no through holes for mounting are mounted on the A-side and the B-side of the motor circuit board 1. As shown in FIG. 1A, a motor driving IC 12 and chip resistors 13, 14 and chip capacitors 15-20 constituting a peripheral circuit of the motor driving IC 12 and other components are mounted on the A-side. As shown in FIG. 1B, hall elements 21, a chip resistor 24, chip capacitors 25-27 and other components are mounted on the B-side.

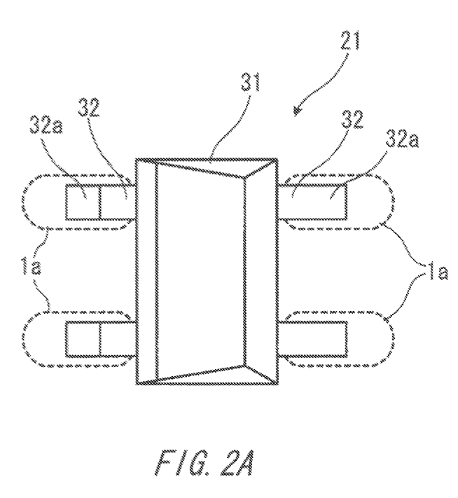

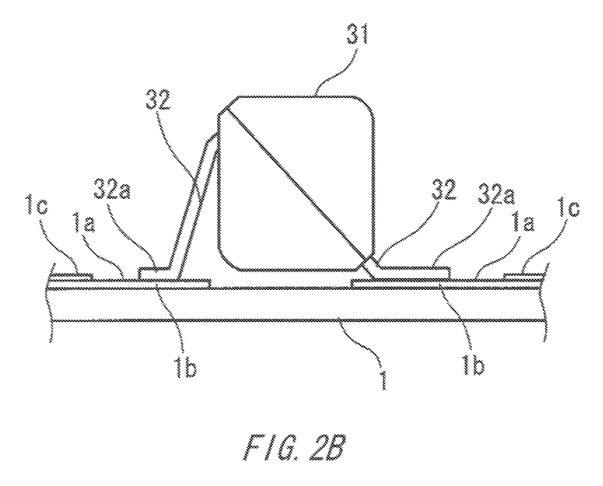

FIGS. 2A and 2B show an example of a hall element that is mounted on the motor circuit board according to the first preferred embodiment. FIG. 2A is a plan view, and FIG. 2B is a side elevation view. The hall element 21 has a plastic package 31 of a size approximately 1.2 mm×2 mm in a plan view and four terminal pins 32 protruding from both edges by two pins each. End portions 32a of these four terminal pins 32 are soldered for electric connection to soldering lands 1a on the motor circuit board 1 in a reflowing step. A width of the terminal pin 32 is approximately 0.3 mm, and the soldering land 1a has an elliptical shape of approximately 0.5 mm×0.8 mm, for example. Note that a resist 1c is printed over copper patterns 1b as shown in FIG. 2B, and a part where this resist 1c is removed for exposing the copper pattern 1b corresponds to the soldering land 1a.

The hall element 21 includes a bridge circuit made up of four magnetoresistance elements. Four nodes of the bridge circuit are drawn out by the terminal pins 32. A predetermined voltage is applied between two of the four terminal pins 32, and a voltage generated between other two of the four terminal pins 32 is outputted as a detected output voltage. This output voltage varies to a positive or a negative value in accordance with a proximate magnetic field (magnetic flux density). This output voltage is inputted to the motor driving IC 12 and is shaped to be a rectangular wave signal by a differential amplifier circuit embedded in the motor driving IC 12. This rectangular wave signal is used as a signal showing a rotation speed (and a rotation phase) for controlling a motor drive.

As shown in FIG. 1B, three mounting portions of the hall element 21 are arranged on the B-side of the motor circuit board 1 at a constant pitch (at an angle interval of 40 degrees in this example) in the circumferential direction. When a rotor magnet of the motor rotates, the output voltage of the hall element 21 alters periodically. This output voltage is supplied to the motor driving IC 12 for detecting a rotation speed or a rotation phase. Therefore, a mount position of the hall element 21 must be controlled accurately. If the mount position of the hall element 21 is shifted, it is difficult to detect a magnetic pole position of the rotor correctly. As a result, it may become difficult to control the rotation speed of the motor (rotor).

Mounting of the hall element 21, the motor driving IC 12 and other surface mount components on the motor circuit board 1 is performed by using a machine called a mounter. A control data including mount positions of the surface mount components on the motor circuit board 1 is created and registered in the mounter. The surface mount components are temporarily fixed to the motor circuit board 1 by flux or the like, and a heat treatment is performed on the motor circuit board 1 in a reflow oven so that the terminal pins of the surface mount components are soldered to the soldering lands. Actually, a mass circuit board including a plurality of motor circuit boards 1 connected via perforation portions is processed by using the mounter and the reflow oven.

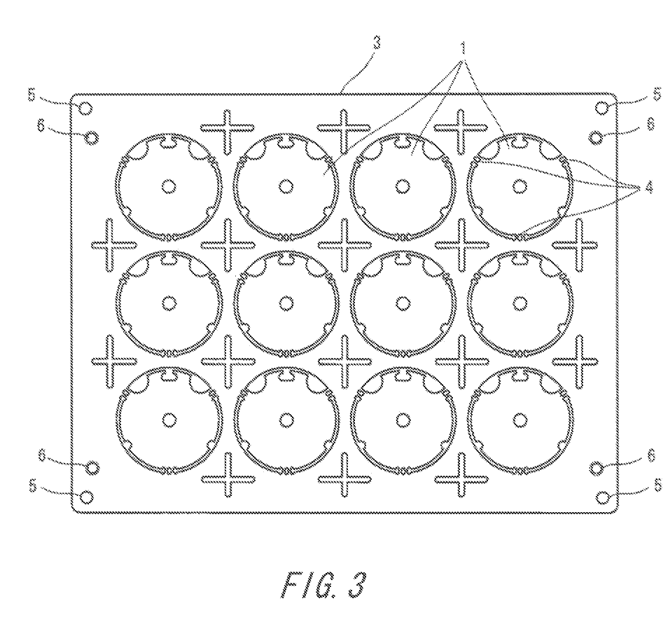

FIG. 3 is a plan view of the mass circuit board that includes a plurality of the motor circuit boards of this preferred embodiment. In this preferred embodiment, 12 motor circuit boards 1 are arranged in three rows and four columns, and they are connected to each other so as to form a mass circuit board 3 of substantially a rectangular shape. The motor circuit boards 1 are connected to the mass circuit board 3 via three perforation portions 4. After the process using the mounter and the reflow oven is finished, the perforation portions 4 are cut by the press machine so that each of the motor circuit boards 1 is cut off from the mass circuit board 3. The mass circuit board 3 that has a substantially rectangular shape, and four corners thereof are provided with through holes 5 for fixing to the mounter or a tool in the reflow oven. At the vicinity of the through holes 5, there are four sets of marks and holes 6 for checking a pattern shift.

A control data for the mounter including mount positions of the surface mount components can be created from a CAD data that was used for designing the patterns of the motor circuit board 1 (i.e., the mass circuit board 3) described above, and the data is registered in the mounter. Actually, however, there may occur some errors in dimensions of the manufactured motor circuit board 1 (mass circuit board 3) due to a print shift, a punch shift or the like in the manufacturing process. As a result, mount positions of the surface mount components may be shifted from target positions. In general, test mounting is performed before real mounting (mass production), and deviation of the mount position is checked visually, and correction of the control data is performed if necessary. As described above, the mount position of the hall element 21 must be controlled accurately in particular.

The visual check of mount positions is performed by using a magnifying glass, for example, and by observing a relative position between the end portions of the terminal pins and the soldering lands. In FIGS. 2A and 2B for example, as described above, a width of the terminal pin 32 is 0.3 mm, while the soldering land la has a size of 0.5 mm×0.8 mm that is much larger than the width of the terminal pin 32. Therefore, it may be checked whether or not the end portion 32a of the terminal pin 32 is substantially in the middle of the soldering land 1a, for example. However, this check is difficult to be accurate because there are individual differences of inspection operators. In particular, it is difficult to detect a position shift in the longitudinal direction of the terminal pin 32 compared with a position shift in the width direction of the same.

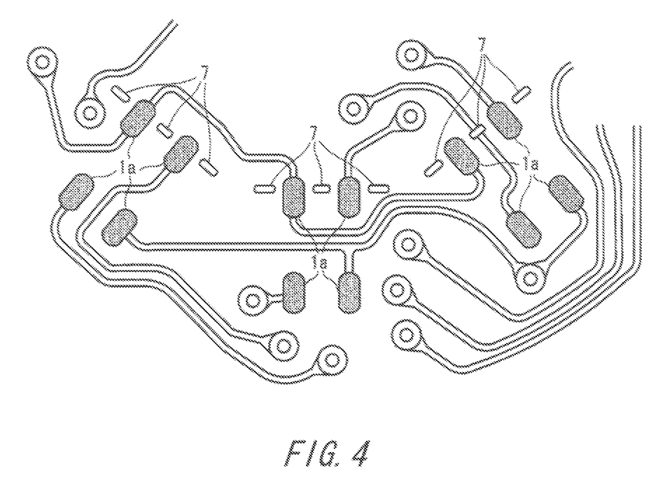

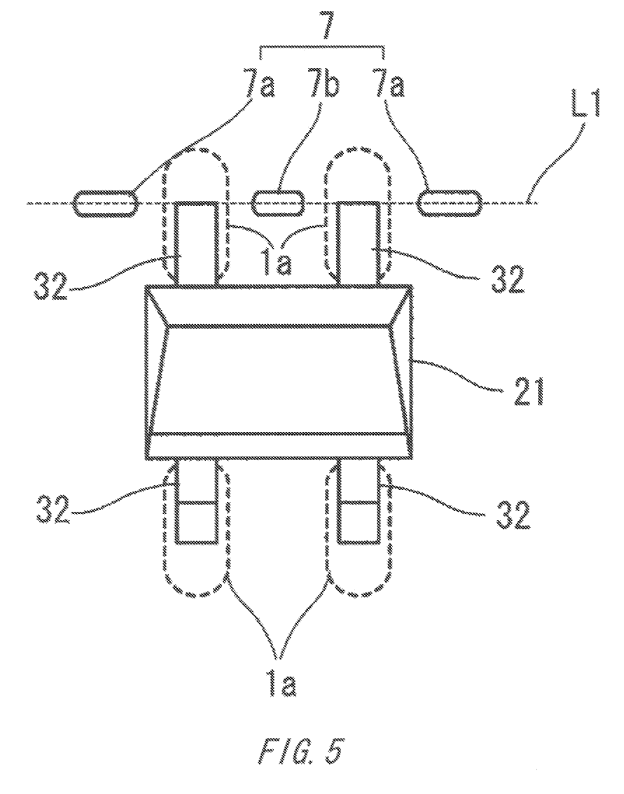

Therefore, the motor circuit board 1 of this example has visual inspection marks 7 printed on the same that facilitates and secures the visual check of the mount position of the hall element 21 as shown in FIG. 4. FIG. 4 is a plan view of a part of the motor circuit board showing places on which the hall elements are mounted and their surrounding patterns with visual inspection marks according to this preferred embodiment. In addition, FIG. 5 is an enlarged view showing a relationship between terminal pins of the hall element and the visual inspection marks according to this preferred embodiment.

As shown in FIG. 4, the visual inspection marks 7 are arranged at vicinities of the soldering land 1a in three portions to which the hall elements 21 are mounted. The visual inspection marks 7 are printed by using a silk pattern (i.e., a second resist pattern) for example, which is printed on the resist. The silk pattern is usually used for printing contours and signs of components that are mounted, and it is usually printed in white color. If the silk pattern is omitted, the visual inspection marks 7 can be printed by the resist as hollow marks.

As shown in FIG. 5, the visual inspection marks 7 include a pair of slender marks 7a that are arranged so as to sandwich two soldering lands 1a to which two terminal pins 32 protruding from one edge of the hall element 21 are soldered. Then, if the hall element 21 is mounted at a correct position, tips of the two terminal pins 32 arranged in a row are positioned on a straight line L1 that connects the pair of slender marks 7a. The pair of slender marks 7a is arranged (printed) in this way.

Therefore, in the visual inspection of the mount position of the hall element 21 that is mounted for the test, positions of tips of the terminal pins 32 are checked with respect to the straight line L1 connecting the pair of slender marks 7a as a reference, so that a position shift in the longitudinal direction (i.e., protruding direction, the vertical direction in FIG. 5) of the terminal pins 32 can be detected easily and accurately. More specifically, if the tips of the two terminal pins 32 arranged in a row are positioned on the straight line L1 that connects the pair of slender marks 7a, it can be determined to be at the correct mount position.

Concerning a position shift in the width direction of the terminal pin 32 (in the lateral direction shown in FIG. 5), it may be checked whether or not the tip portions of the two terminal pins 32 are positioned uniformly between the pair of slender marks 7a. In addition, the motor circuit board 1 of this preferred embodiment includes a third slender mark 7b that is printed at a middle position between the pair of slender marks 7a and between two soldering lands 1a. In other words, the visual inspection mark 7 includes a pair of slender marks 7a and a slender mark 7b positioned at the middle position between them. Therefore, the hall element 21 is mounted in such a way that each of tips of two terminal pins 32 protruding from an edge of the hall element 21 is positioned between two of three slender marks 7a, 7b and 7a printed to be aligned on a straight line at a constant pitch. As a result, it can be performed more easily and more correctly to inspect visually whether or not a position shift exists not only in the longitudinal direction but also in the width direction of the terminal pins.

However, the third slender mark 7b can be omitted. It is necessary to print at least the pair of slender marks 7a arranged so as to sandwich the plurality of soldering lands 1a aligned in a row. The following second preferred embodiment will be described with reference to such a structure.

### Second Preferred Embodiment

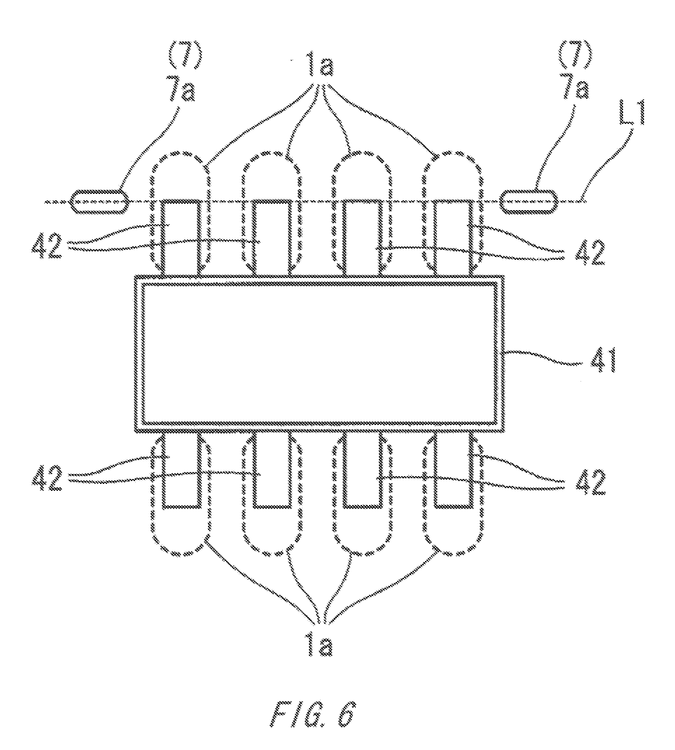

FIG. 6 is an enlarged view showing a relationship between terminal pins of a surface mount component and visual inspection marks in a second preferred embodiment of the present invention. In this preferred embodiment, a surface mount component 41 to be inspected visually is not a hall element in the first example but an electronic component such as an integrated circuit having many terminal pins 42 protruding from its edge. In this preferred embodiment, as shown in FIG. 6, total eight terminal pins 42 protrude from both sides of a package of the electronic component 41, four pins 42 from each side. Similarly to the first preferred embodiment, a pair of slender marks 7a is printed so as to sandwich a plurality of soldering lands 1a aligned in a row for the terminal pins 42. When the electronic component 1 is mounted on the correct position, the tips of the four terminal pins 42 aligned in a row are positioned on a straight line L1 connecting the pair of slender marks 7a. The pair of slender marks 7a is arranged (printed) in this way. In this preferred embodiment, the visual inspection mark 7 is made up of only the pair of slender marks 7a.

In this preferred embodiment too, a position shift in the longitudinal direction (i.e., protruding direction, the vertical direction in FIG. 6) of the terminal pins 42 can be detected easily and accurately by checking positions of tips of the terminal pins 42 with respect to the straight line L1 connecting the pair of slender marks 7a as a reference. More specifically, if the tips of the four terminal pins 42 arranged in a row are positioned on the straight line L1 that connects the pair of slender marks 7a, it can be determined to be at the correct mount position. In addition, concerning a position shift in the width direction (i.e., the lateral direction in FIG. 6) of the terminal pin 42, it may be checked whether or not the tip portions of the four terminal pins 42 are positioned uniformly between the pair of slender marks 7a.

Although examples of preferred embodiments of the present invention are described above, the motor circuit board and the visual inspection method of an electronic component mount position according to the present invention can be embodied variously without limiting to these examples.

While example preferred embodiments of the present invention have been shown and described, it will be understood that the present invention is not limited thereto, and that various changes and modifications may be made by those skilled in the art without departing from the scope of the present invention as set forth in the appended claims and their equivalents.

What is claimed is:

1. A circuit board arranged to mount a surface mount electronic component, comprising:
a plurality of soldering lands arranged to receive a plurality of terminal pins protruding from a package of the electronic component; and
visual inspection marks arranged at a vicinity of the plurality of soldering lands; wherein
the visual inspection marks include a pair of slender marks arranged so as to sandwich the plurality of soldering lands aligned in a row.

2. The circuit board according to claim 1, further comprising the electronic component, wherein the electronic component includes at least two terminal pins protruding from each of opposite sides of the package, and the pair of slender marks are arranged such that two of the soldering lands to which two of the terminal pins protruding from one side of the package are soldered are sandwiched between the pair of slender marks.

3. The circuit board according to claim 2, further comprising a third slender mark arranged at a middle position between the pair of slender marks and between the two soldering lands.

4. The circuit board according to claim 3, wherein a length of the third slender mark in the longitudinal direction is shorter than a length of each of the pair of slender marks in the longitudinal direction.

5. The circuit board according to claim 2, wherein the pair of slender marks are arranged so that tips of the terminal pins soldered to the plurality of soldering lands are positioned on a straight line connecting the pair of slender marks.

6. The circuit board according to claim 1, wherein a width of each slender mark is within a range of about 0.1 mm to about 0.3 mm, and a length of each slender mark is within a range of about 0.3 mm to about 0.6 mm.

7. A motor circuit board including a surface mount electronic component mounted thereon, the circuit board being attached to a motor including a rotor and a stator, the circuit board comprising:
a plurality of soldering lands to which a plurality of terminal pins protruding from a package of the electronic component are soldered; and
visual inspection marks arranged at a vicinity of the plurality of soldering lands; wherein
the visual inspection marks include a pair of slender marks arranged so as to sandwich the plurality of soldering lands aligned in a row; and
the pair of slender marks are arranged so that tips of the plurality of terminal pins of the electronic component that are soldered to the plurality of soldering lands are positioned on a straight line connecting the pair of slender marks.

8. The motor circuit board according to claim 7, wherein the electronic component is a hall element that is arranged at a position for detecting magnetic poles of a rotor magnet of the rotor, the electronic component includes at least two terminal pins protruding from each of opposite sides of the package, and the pair of slender marks are arranged such that two of the soldering lands to which two of the terminal pins protruding from one side of the package are soldered are sandwiched between the pair of slender marks.

9. The motor circuit board according to claim 8, further comprising a third slender mark arranged at a middle position between the pair of slender marks and between the two soldering lands.

10. The motor circuit board according to claim 9, wherein a length of the third slender mark in the longitudinal direction is shorter than a length of each of the pair of slender marks in the longitudinal direction.

11. The motor circuit board according to claim 7, wherein a width of the slender mark is within a range of about 0.1 mm to about 0.3 mm, and a length of the slender mark is within a range of about 0.3 mm to about 0.6 mm.

12. A method for visually inspecting a mount position of a surface mount electronic component mounted on a circuit board, the method comprising the steps of:
printing a pair of slender marks on the circuit board so that a plurality of soldering lands to which a plurality of terminal pins protruding from a package of the electronic component are soldered are sandwiched between the pair of slender marks; and
inspecting whether or not tips of the plurality of terminal pins of the electronic component aligned in a row are positioned on a straight line connecting the pair of slender marks.

13. The method according to claim 12, wherein the electronic component is a hall element having at least two terminal pins protruding from each of opposite sides of the package, and the pair of slender marks are printed on the circuit board so that the pair of slender marks sandwich two of the soldering lands to which two of the terminal pins protruding from one side of the package are soldered.

14. The method according to claim 13, further comprising:
printing a third slender mark at a middle position between the pair of slender marks and between the two soldering lands; and
inspecting whether or not the third slender mark is positioned at a middle position between the tips of the two terminal pins of the mounted electronic component.

15. The method according to claim 12, wherein a width of the slender mark is within a range of about 0.1 mm to about 0.3 mm, and a length of the slender mark is within a range of about 0.3 mm to about 0.6 mm.
